(19) United States
(12) Patent Application Publication
(10) Pub. No.: US 2023/0314660 A1
(43) Pub. Date: Oct. 5, 2023

(54) MANUFACTURING AN OPTICAL ELEMENT

(71) Applicant: ams Sensors Singapore Pte. Ltd., Singapore (SG)

(72) Inventors: Barbara Horvath, Eindhoven (NL); Simon Gubser, Eindhoven (NL)

(73) Assignee: ams Sensors Singapore Pte. Ltd., Singapore (SG)

(21) Appl. No.: 18/041,977

(22) PCT Filed: Aug. 25, 2021
(86) PCT No.: PCT/SG2021/050498

§ 371 Date: Feb. 16, 2023

(30) Foreign Application Priority Data
Aug. 27, 2020 (GB) 2013420.1

(51) Int. Cl. G02B 1/04; G02B 3/00

(52) U.S. Cl. CPC G02B 1/041; G02B 3/0031; G02B 5/0268

(57) ABSTRACT

A method of manufacturing an optical element, the method comprising: providing a substrate; providing a tool comprising, on a first side, a section defining a surface structure of the optical element; aligning the tool and the substrate with respect to each other and bringing the tool and a first side of the substrate together, with material between the tool and the substrate; positioning a transparent masking structure adjacent to the substrate onto which the material has adhered, the masking structure comprising a masking layer; emitting light through the masking structure to be incident on a portion of the material to cure said potion of the material, wherein the masking layer prevents light from being incident on a remaining portion of the material such that the remaining portion of the material is uncured; and removing the uncured remaining portion of the material.

### TECHNICAL FIELD

This disclosure relates to manufacturing optical elements.

### BACKGROUND

Small optoelectronic modules such as imaging devices and light projectors employ lenses or other optical elements to achieve desired optical performance. Optical elements include transparent diffractive and/or refractive optical elements for influencing an optical beam. Optical elements can be produced by replication. In some applications, replicating optical elements includes forming a portion of a liquid material, such as an epoxy, into a desired shape using, for example, a portion of a tool, and subsequently curing the material. In some cases, a replicated optical element is formed along with a yard formed in the vicinity of the replicated optical element. A yard comprises material that is included in excess of the material required to form the optical element, where the excess material is included to ensure complete coverage of the portion of the tool.

### SUMMARY

The present disclosure relates to manufacturing optical elements without yards.

According to one aspect of the present disclosure there is provided a method of manufacturing an optical element, the method comprising: providing a substrate; providing a tool comprising, on a first side, a section defining a surface structure of the optical element; aligning the tool and the substrate with respect to each other and bringing the tool and a first side of the substrate together, with material between the tool and the substrate; positioning a transparent masking structure adjacent to the substrate onto which the material has adhered, the masking structure comprising a masking layer; emitting light through the masking structure to be incident on a portion of the material to cure said potion of the material, wherein the masking layer prevents light from being incident on a remaining portion of the material such that the remaining portion of the material is uncured; and removing the uncured remaining portion of the material.

Embodiments of the present disclosure advantageously enable a higher density of optical elements to be manufactured on a single substrate, where otherwise the density of the optical elements on the substrate would be limited by the area of the yard(s). This results in a more efficient manufacturing process as the number of optical elements that can be manufactured at any one time is increased.

Furthermore, the manufacturing process may be greatly simplified, as there is no need to remove the yard prior to installation of the optical element in a module.

As there is no need to remove a yard, optical elements manufactured without yards according to embodiments of the present disclosure can exhibit improved reliability over optical elements with yards, where removal of the yard (e.g. using a laser cutter or by mechanically cutting or breaking the yard off the optical element) can otherwise result in the optical element being left with a rough edge and/or unintended portions of the yard being left attached, and/or portions of the optical element being unintentionally removed. This improved reliability is advantageous as the optical performance of small optical elements is highly sensitive to variations in size and/or shape. The improved reliability is also advantageous where applications of small optical elements require high precision positioning, for example installation in small optoelectronic modules.

In addition, optical elements without yards can further exhibit improved optical performance over optical elements with yards, as during use unwanted light that might otherwise be collected by the yard (or any remaining portion of the yard where the yard has been removed) is not collected, and/or light that is collected by the optical element will not be redirected along an unintended path, for example due to transmission, reflection and/or refraction at an interface between the yard (or yard portion) and air and/or an interface between the optical element and the yard (or yard portion).

Providing a transparent masking structure adjacent to the substrate onto which the material is adhered is advantageous as the transparent masking structure can be used repeatedly with several different substrates and/or tools, providing a simplified and more efficient manufacturing process.

In some embodiments, the masking structure is positioned below the substrate such that the light is incident on a second side of the substrate, opposite the first side, before being incident on the portion of the material. This arrangement can be advantageous as the light passes through only the thin masking structure and substrate, minimising the risk of unintentionally curing the remaining portion of material due to divergence and/or scattering of the light. Alternatively, the tool is made of a transparent material, and the masking structure is positioned above the tool such that the light passes through the tool before being incident on the portion of the material.

In some embodiments, removing the uncured remaining portion of the material comprises washing the uncured remaining portion of the material away with a solvent. Alternatively or additionally, removing the uncured remaining portion of the material can comprise extracting the uncured remaining portion of the material via one or more channels. Extracting the uncured remaining portion may be advantageous as it enables a further increase in the density of replicated optical elements, since no additional tool volume or substrate area is required for the remaining portion. In some embodiments, the tool comprises the one or more channels. In some embodiments, the tool comprises a first portion made of a first material and a second portion made of a second material, and the one or more channels extend through both the first portion and the second portion. Alternatively, the one or more channels may extend through the second portion and along an interface between the first portion and the second portion of the tool. In other embodiments, the substrate comprises the one or more channels.

In some embodiments, the masking layer is made of metal.

In some embodiments, the light is collimated light. This can be advantageous as it further minimises the risk of unintentionally curing the remaining portion of material, which may occur in cases where the light is not collimated.

In some embodiments, the light is ultraviolet light.

In some embodiments, the transparent masking structure is made of glass.

### BRIEF DESCRIPTION OF THE PREFERRED EMBODIMENTS

Some embodiments of the disclosure will now be described by way of example only and with reference to the accompanying drawings, in which:

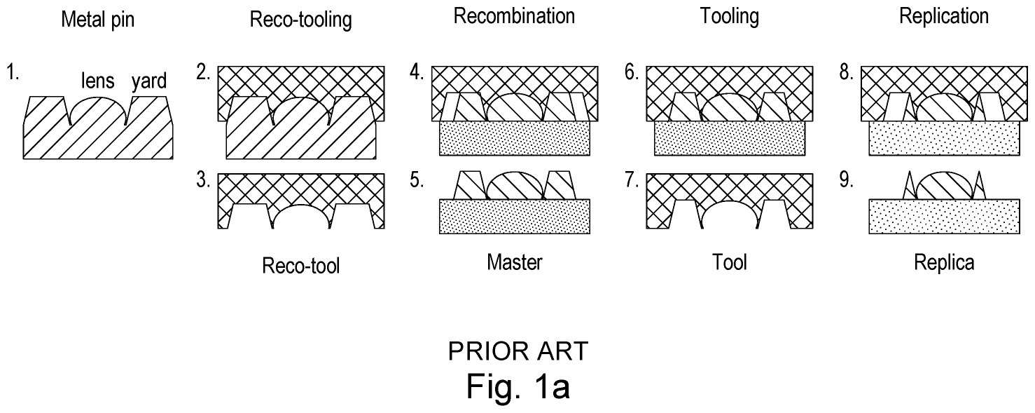

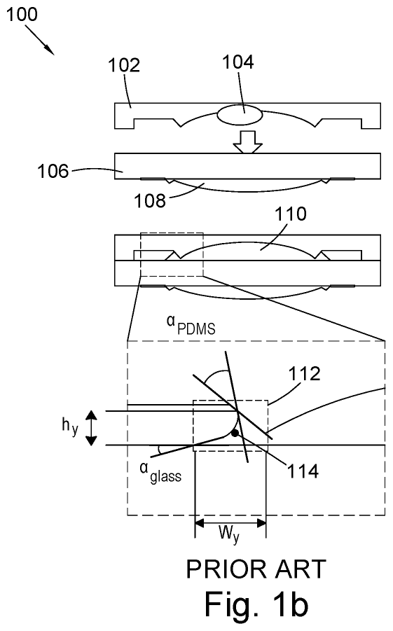

FIGS. 1a and 1b illustrate a known replication process to manufacture an optical element;

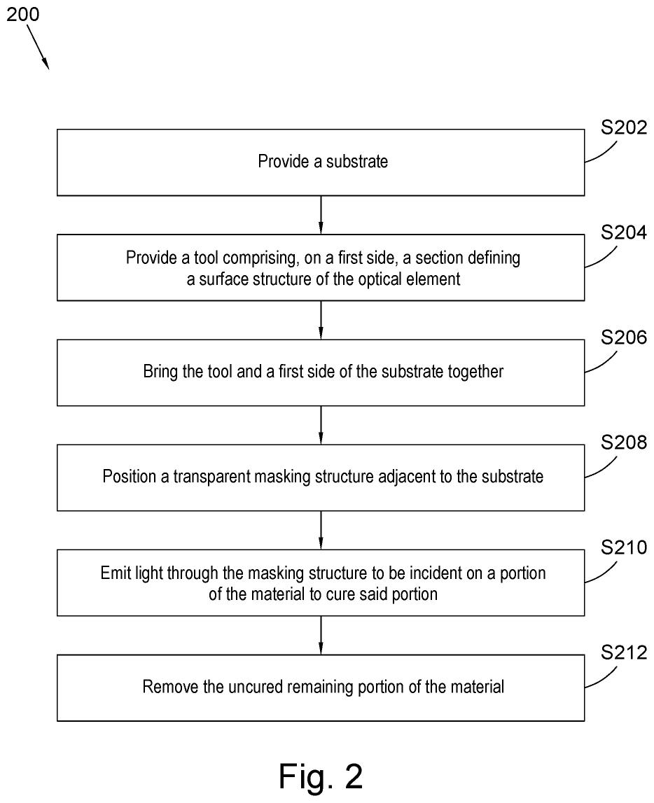

FIG. 2 illustrates a process for manufacturing an optical element according to the present disclosure;

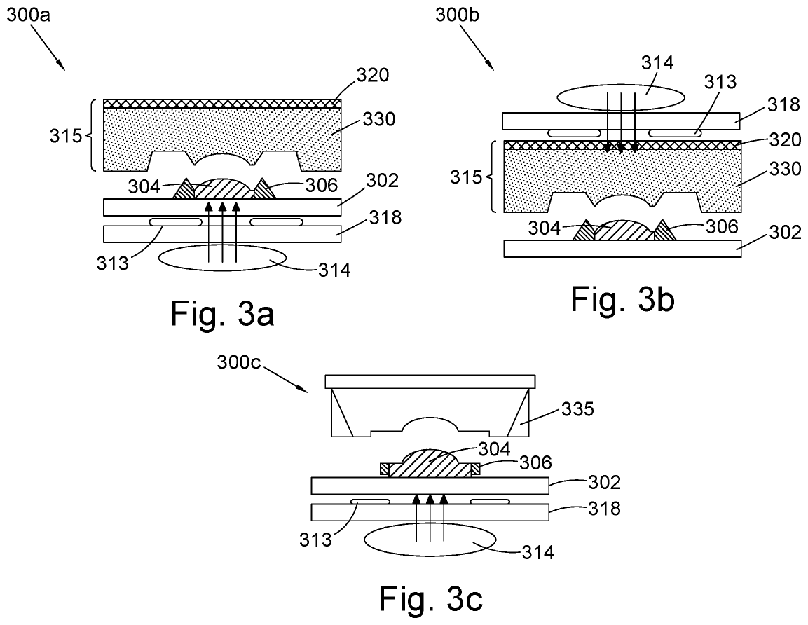

FIGS. 3a to 3c illustrate various examples of a process for manufacturing an optical element according to the present disclosure;

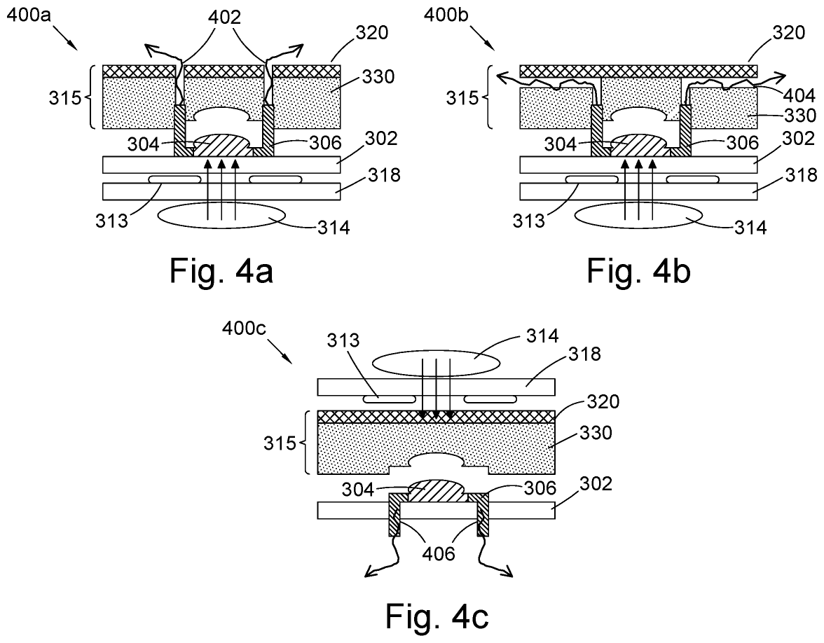

FIGS. 4a to 4c illustrate various examples of a process for manufacturing an optical element according to the present disclosure in which uncured material is removed via one or more channels; and

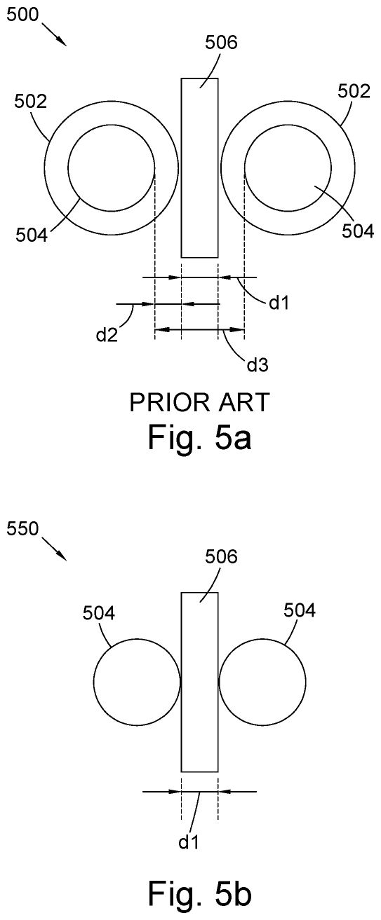

FIGS. 5a and 5b illustrate a comparison between optical elements produced by know replication processes and optical elements produced by the process for manufacturing an optical element according to the present disclosure.

### DETAILED DESCRIPTION OF THE PREFERRED EMBODIMENTS

Embodiments will now be described by way of example only with reference to the accompanying figures.

FIGS. 1a and 1b illustrate a known replication process to manufacture an optical element.

In FIG. 1a, steps 1 to 9 of the replication process are illustrated. A metal pin is shown in step 1 having portions shaped corresponding to an optical element (in this case a lens) and a yard.

In steps 2 and 3 of FIG. 1a, the metal pin is employed in the formation of a recombination tool (reco-tool). The recombination tool comprises a replication surface comprising a (negative) copy of the surface of the metal pin.

In steps 4 and 5 of FIG. 1a, a recombination process is performed. A material (e.g. epoxy) is applied to the recombination tool and/or to a substrate. The recombination tool is subsequently brought into contact with the substrate and the material fills the portion of the recombination tool shaped corresponding to an optical element. Excess material fills at least part of the portion of the tool shaped corresponding to the yard. The material is then cured and the recombination tool is removed. The cured material on the substrate provides a master. The recombination process may be repeated across the substrate, so that the master comprises a plurality of identical optical elements each having an associated yard. Alternatively, the master may comprise a single optical element having a yard.

The master is subsequently employed in the formation of a tool by a similar process to the process in which the metal pin is employed in the formation of the recombination tool (steps 6 and 7 of FIG. 1a). The tool comprises a replication surface comprising a (negative) copy of the surface of the master.

Steps 8 and 9 of FIG. 1a illustrate a replication process. A material (e.g. epoxy) is applied to the tool and/or to a substrate and the tool is subsequently brought into contact with the substrate. The material fills a portion, or portions, of the tool shaped corresponding to an optical element. Excess material fills at least part of a portion, or portions, of the tool shaped corresponding to a yard. The material is subsequently cured and the tool is removed. A replica, comprising one or more optical elements with yards on the substrate, remains.

In the present disclosure, the terms “optical element” and “yard” may describe features of a master or a replica, and the methods described herein are applicable to the both the recombination and the replication processes. The terms “replication” and “replication process”, as used herein, may therefore describe the formation of a master in a recombination process, or equally the formation of a replica in a replication process. The tool referred to herein may be a replication tool or a recombination tool.

FIG. 1b illustrates in more detail a known replication process to manufacture an optical element showing a cross section through a tool 102 and a substrate 106. A preferred material of the tool 102 is polydimethylsiloxane (PDMS), but other materials may be used. The tool 102 comprises a replication surface comprising one or more replication sections, the surface of each of which is a (negative) copy of a surface shape of an optical element to be manufactured. The replication section(s) can be convex and thus define a concave optical element surface, or be convex and define a concave optical element surface.

The substrate 106 has a first upper side and a second lower side and can be any suitable material, for example glass. FIG. 1b illustrates forming an optical element 110 that extends from the first upper side of the substrate 106. As shown in FIG. 1b, the substrate 106 has an optical element 108 that extends from the second lower side of the substrate 106

For replicating the replication surface of the tool 102, a replication material 104 (e.g. epoxy) is applied to the substrate 106, or the tool 102, or both the tool 102 and the substrate 106.

After application of the replication material 104, the substrate 106 and the tool 102 are aligned with respect to each other. Subsequent to the alignment, the substrate 106 and the tool 102 are brought together. Once the replication material 104 has been hardened the tool 102 is removed.

During replication, excess material or epoxy applied during jetting normally overflows the region of interest and forms a yard 112 when the tool 102 and the substrate 106 (e.g., glass) are brought into contact. The yard 112 is typically a circular shape. This circular yard 112 does not perform any optical function, it results from more epoxy 104 being added during the replication process than each structure requires, causing an overflow. The additional epoxy 104 ensures that the complete volume of replication material needed for a particular structure is available (as the tolerance of the epoxy volume is not zero), and the extra fluid pools to form the yard 112. As shown in FIG. 1b, the yard 112 has an epoxy meniscus 114. Typically, the yard 112 has a height h_{y} of 30-300 μm and a width w_{y} of 200-400 μm.

The yard 112 results in a reduced density of optical elements 108 that can be produced on a single substrate 106. As the yard 112 comprises the same material 104 as the optical element 108, when the optical element 108 is in use, for example as a component in an optoelectronic module, the yard 112 may also result in the collection of unwanted light. Alternatively, or in addition, the yard 112 may cause the light to follow an unintended path due, for example, to reflection, transmission, refraction or any other light interaction process at an interface between the yard and its surroundings (e.g. air) and/or an interface between the yard and the optical element.

We now refer to FIGS. 2, 3 and 4, which illustrate a process 200 for manufacturing an optical element according to embodiments of the present disclosure.

The optical elements referred to herein may be a lens. It will be appreciated that this is merely an example and the optical element may be any element which influences light that is irradiating it including but not restricted to a lens, collimator, pattern generator, deflector, mirror, beam splitters, diffractive prism, diffuser, micro lens array, elements for decomposing the radiation into its spectral composition, etc., and combinations thereof.

As illustrated in FIG. 2, as an initial step S202 a substrate 302 is provided.

In a second step S204, a tool 315, 335 is provided comprising, on a first side, a section defining a surface structure of the optical element 304. The section of the tool may have a circular shape however, this is just an example and embodiments extend to the shape of other shaped optical elements (e.g. some lenses are squared shape).

In a third step S206, the tool 315, 335 and a first side of the substrate 302 are brought together with material (e.g. epoxy) between the tool 315, 335 and the substrate 302. The material may be applied to the substrate 302 or the tool, or both the tool and the substrate 302. When the material is applied to the tool, when the tool and the substrate 302 are brought together, the material is transferred to the first side of the substrate 302. Epoxies, acrylates, ormocer materials, resists, and hybrid materials are examples of the material which can be used in embodiments of the present disclosure to form the optical element.

In a fourth step S208, a transparent masking structure 318 is positioned adjacent to the substrate 302.

In a fifth step S210, light 314 is emitted through the masking structure 318 to be incident on a portion 304 of the material to cure this portion of the material.

In a sixth step S212, an uncured remaining portion 306 of the material is removed.

The steps S202 to S212 of FIG. 2 will now be described in more detail with reference to FIGS. 3 and 4.

FIG. 3a schematically illustrates an example 300a of the process 200. FIG. 3a shows a cross section through the substrate 302 and the tool 315 provided in steps S202 and S204 of process 200. The substrate can be any suitable material, for example glass. A preferred material of the tool 315 is polydimethylsiloxane (PDMS) but other materials may be used. The tool 315 may be provided with a rigid back plate 320 in addition to a softer material portion 330, which is for example PDMS, whereby this softer material portion 330 is to come into contact with the material forming the optical element. The tool 315 has a section defining a (negative of a) surface structure of an optical element. For example, where the optical element to be manufactured has a concave surface profile, the section of the tool 315 has a convex profile. In another example, where the optical element to be manufactured has a convex surface profile, the section of the tool 315 has a concave profile.

The tool 315 is then brought into contact with the first side of the substrate 302, with material between the tool 315 and the substrate 302 (step S206 of process 200). The material may be applied, for example, to the first side of the substrate 302, to the tool 315, or to both the first side of the substrate 302 and the tool 315. In example 300a, the material may specifically be applied to the softer material portion 330 of the tool 315. The material may be applied immediately before tool 315 and the first side of the substrate 302 are brought together. The material may be applied, for example, by squirting or jetting one droplet or a plurality of droplets, by a dispensing tool that may for example work in an inkjet-printer-like manner. Alternatively, or in addition, the material may be applied between the tool 315 and the first side of the substrate 302 after they have been brought together. Where the material is applied after the tool 315 and the first side of the substrate 302 have been brought together, the material may be supplied (e.g. by injection) into a gap formed between the tool 315 and the first side of the substrate 302. The material may be epoxy or any suitable curable material.

When the tool 315 and the first side of the substrate 302 are brought together with material between them. A portion 304 of the material fills the section of the tool 315 defining the (negative of a) surface structure of an optical element. A remaining excess portion 306 of material is squeezed outside of the section of the tool.

A transparent masking structure 318 is then positioned adjacent to the substrate (step S208 of process 200). The masking structure 318 comprises a suitably transparent material (e.g. glass) through which light can pass on which is disposed a masking layer 313. The masking layer may be made of metal (e.g. chromium), black ink or paint, or any other suitably opaque material. In the example 300a illustrated in FIG. 3a, the masking structure 318 is positioned below the substrate 302. In another example 300b, illustrated in FIG. 3b, the masking structure 318 is positioned above the tool 315. A light source is positioned such that emitted light 314 is then incident on the masking structure 318 (step S210 of process 200). The light 314 has wavelength(s) capable of curing the optical element material, and which are capable of being transmitted by the masking structure 318 and of being absorbed, reflected and/or otherwise blocked by the masking layer 313. For example, light 314 may be ultraviolet (UV) light. Embodiments are not limited to the light 314 being UV light, and other light having other wavelengths may be used. For example, visible light curing is also possible. When visible light is used, the same materials (to be cured) can be used as with UV light but with different photoinitiators.

In the present disclosure, the term “transparent” describes materials that are transmissive to the light 314, and the term “opaque” describes materials that are not transmissive to the light 314.

The light 314 may be collimated. This may prevent the light 314 from diverging following transmission by the masking structure 314, which may otherwise result in unintended partial or total curing of the uncured portion 306 of the material.

Where the masking structure 318 is positioned below the substrate 302, as illustrated in FIG. 3a, substrate 302 comprises a transparent material, and the light 314 is transmitted by the substrate 302. Where the masking structure 318 is positioned above the tool 315, as illustrated in FIG. 3b, the rigid back plate 320 and the softer material portion 330 of tool 315 both comprise transparent materials, and the light 314 is transmitted by the rigid back plate 320 and the softer material portion 330 of tool 315.

The transmitted light 314 is incident on the portion 304 of the material that fills the section of the tool 315 defining the (negative of a) surface structure of an optical element, and the portion 304 is subsequently cured by the light that is incident on it. The masking layer 313 prevents the light from reaching the remaining portion 306 of the material, and the remaining portion 306 is not cured by the light.

A further example 300c of process 200 is illustrated in FIG. 3c, in which an opaque tool 335 is provided in step S204. The opaque tool 335 may comprise a metal. Example 300c may correspond to a recombination process. In example 300c, the masking structure 318 is positioned below the substrate 302 and the light 314 is emitted through the masking structure 318 and the substrate 302.

The light 314 may be emitted through the masking structure 318 (step S210 of process 200) while the tool 315 is in contact with the substrate 302. Alternatively the light 314 may be emitted through the masking structure 318 (step S210 of process 200) while the tool 315 is in a raised position above (not in contact with) the substrate 302.

When the portion 304 of the material has been cured, the remaining uncured portion 306 of the material is removed (step S212 of process 200).

The remaining uncured portion 306 of the material may be removed by washing the material away, e.g. with a solvent. Alternatively, or in addition, the remaining uncured portion 306 of the material may be removed via one or more channels 402, 404, 406.

Examples of process 200 in which the remaining uncured portion 306 of the material is removed in step S212 via one or more channels 402, 404, 406 are illustrated in FIGS. 4a to 4c.

FIG. 4a illustrates an example 400a in which one or more channels 402 extend upwardly through the tool 315. The channels in example 400a extend through the soft material portion 330 and the rigid back plate 320 of the tool 315. In an alternative example, the tool may comprise a single piece of material, such as the opaque tool 335 illustrated in FIG. 3c, and the channels may pass through the full thickness of the tool material. In example 400a, the uncured portion 306 of the material is removed by passing vertically upwards through the channels 402. The removed uncured portion 306 of the material may be extracted from one or more channel openings of the tool 315.

FIG. 4b illustrates a further example 400b in which one or more channels extend vertically upwards through the soft material portion 330 of the tool 315, and along an interface between the soft material portion 330 and the rigid back plate 320. The uncured portion 306 of the material is removed by passing vertically upwards through the portions of the channels 404 that extend vertically upwards through the soft material portion 330 of the tool 315, and subsequently passing horizontally through the portions of the channels 404 that pass along the interface between the soft material portion 330 and the rigid back plate 320. The removed uncured portion 306 of the material may be extracted from one or more channel openings of the tool 315.

In examples 400a and 400b illustrated in FIGS. 4a and 4b, the masking structure 318 is positioned below the substrate 302 and the light 314 is emitted through the substrate 302, where the substrate 302 is transparent. This prevents the light 314 from being otherwise incident on the uncured material 306 in the channels 402, 404 and curing the material in the channels 402, 404. Any cured material in the channels 402, 404 would block the channels 402, 404 and render impossible the extraction of the uncured portion 306 of the material.

FIG. 4c shows an alternative example 400c in which one or more channels 406 extend vertically downwards through the substrate 302. The uncured portion 306 of the material is removed by passing vertically downwards through the channels 406. The removed uncured portion 306 of the material may be extracted from one or more channel openings of the substrate 302.

In example 400c illustrated in FIG. 4c, the masking structure 318 is positioned above the tool 315 and the light is 314 transmitted by the tool 315, where the tool 315 is transparent (where the tool comprises a rigid back plate 320 and a soft material portion 330, where the rigid back plate 320 and the soft material portion 330 are transparent).

This prevents the light 314 from being otherwise incident on the uncured material 306 in the channels 406 and curing the material in the channels 406.

The uncured portion 306 of the material may be removed via the channels 402, 404, 406 by suction (e.g. utilising a vacuum pump). Alternatively, the uncured portion 306 may be forced through the channels 402, 404, 406 by the action of bringing the tool 315 and the substrate 302 together.

Removal of the uncured portion 306 of the material via one or more channels 402, 404, 406 may reduce or remove the need for any additional section or volume of the tool 315 into which the excess material 306 would otherwise overflow from the section of the tool corresponding to the optical element. Where the tool 315 comprises multiple sections corresponding to a plurality of optical elements, this may enable a higher density of those sections on the tool 315 resulting in the production of more optical elements in a single replication process.

FIGS. 5a and 5b illustrate a comparison between optical elements 504 produced by prior art replication processes and the process 200 described in the present disclosure.

FIG. 5a illustrates an arrangement 500 of optical elements 504 produced on a substrate following a prior art replication process. As previously described, excess epoxy or other replication material that overflows the section of the tool corresponding to the optical element 504 forms a yard 502. A minimum distance between optical elements 504 on a substrate is defined by a width d1 of a spacer or dicing region 506, through which the substrate is cut or otherwise separated when the optical elements 504 are singulated into individual components prior to their installation in optoelectronic modules. Where a yard 502 is present, a minimum distance between the spacer or dicing region 506 and the optical element 504 has a width of the yard d2. As previously described, d2 is typically 200-400 μm. Therefore, optical elements 504 with yards 502 are separated on the substrate by a total minimum distance d3, where d3=d1+d2×d2). The overflow of material that forms the yard 502 is generally uncontrollable. Therefore, in some cases, the yard 502 may extend into the spacer or dicing region 506. This may result in cuts across part of the yard during the singulation process, leading to unintended defects in the yard 502 and/or the optical element 504, which may reduce the reliability of the optical elements 504.

FIG. 5b illustrates an arrangement 550 of optical elements 504 produced on a substrate following a replication process according to the present disclosure. As no yard 502 is present, the minimum distance between optical elements 504 is defined only by the width d1 of the spacer or dicing region 506. The arrangement 550 therefore allows an increased area density of optical elements 504 on a substrate in comparison to the prior art arrangement 500. Additionally, the formation of the optical element 504 is controlled by the tool during the replication process. The risk of material extending into the spacer or dicing region 506 is therefore minimised, resulting in fewer defects forming in the optical elements 504 as a result of the singulation process.

Although the disclosure has been described in terms of preferred embodiments as set forth above, it should be understood that these embodiments are illustrative only and that the claims are not limited to those embodiments. Those skilled in the art will be able to make modifications and alternatives in view of the disclosure, which are contemplated as falling within the scope of the appended claims. Each feature disclosed or illustrated in the present specification may be incorporated in any embodiments, whether alone or in any appropriate combination with any other feature disclosed or illustrated herein.

1. A method of manufacturing an optical element, the method comprising:
providing a substrate (302);
providing a tool (315,335) comprising, on a first side, a section defining a surface structure of the optical element;
aligning the tool and the substrate with respect to each other and bringing the tool and a first side of the substrate together, with material between the tool and the substrate;
positioning a transparent masking structure (318) adjacent to the substrate onto which the material has adhered, the masking structure comprising a masking layer (313);
emitting light (314) through the masking structure to be incident on a portion (304) of the material to cure said potion of the material, wherein the masking layer prevents light from being incident on a remaining portion (306) of the material such that the remaining portion of the material is uncured; and
removing the uncured remaining portion of the material.

2. The method of claim 1, wherein the masking structure is positioned below the substrate such that the light is incident on a second side of the substrate, opposite the first side, before being incident on the portion (304) of the material.

3. The method of claim 1, wherein the tool is made of a transparent material, and the masking structure is positioned above the tool such that the light passes through the tool before being incident on the portion (304) of the material.

4. The method of claim 1, wherein said removing comprises washing the uncured remaining portion of the material away with a solvent.

5. The method of claim 1, wherein said removing comprises extracting the uncured remaining portion of the material via one or more channels (402, 404, 406).

6. The method of claim 5, wherein the tool comprises said one or more channels (402,404).

7. The method of claim 6, wherein the tool comprises a first portion (320) made of a first material and a second portion (330) made of a second material, and the said one or more channels (402) extend through both the first portion and the second portion.

8. The method of claim 6, wherein the tool comprises a first portion (320) made of a first material and a second portion (330) made of a second material, and the said one or more channels (404) extend through the second portion and along an interface between the first portion and the second portion of the tool.

9. The method of claim 5, wherein the substrate comprises said one or more channels (406).

10. The method of claim 1, wherein the masking layer is made of metal.

11. The method of claim 1, wherein the light is collimated light.

12. The method of claim 1, wherein the light is ultraviolet light.

13. The method of claim 1, wherein the transparent masking structure is made of glass.
